(19) United States
(12) Patent Application Publication
(10) Pub. No.: US 2018/0308421 A1
(43) Pub. Date: Oct. 25, 2018

(54) DISPLAY PANEL FABRICATED ON A ROUTABLE SUBSTRATE

(71) Applicant: ASM Technology Singapore Pte Ltd, Singapore (SG)

(72) Inventors: Tat Chi CHAN, Hong Kong (HK); Gio Jose Asumo VILLAESPIN, Singapore (SG)

(21) Appl. No.: 15/951,216

(22) Filed: Apr. 12, 2018

Related U.S. Application Data
(60) Provisional application No. 62/488,272, filed on Apr. 21, 2017.

(51) Int. Cl. G09G 3/32; H01L 21/56; H01L 21/48; H01L 21/02; H01L 27/12

(52) U.S. Cl. CPC G09G 3/32; H01L 21/56; H01L 27/12; H01L 21/02172; H01L 21/4814

(57) ABSTRACT

A display panel including a routable substrate is manufactured by depositing a first metallic layer for forming routable conductive traces. A second metallic layer for forming conductive interconnects is then deposited, the second metallic layer having a pattern which is different from the first metallic layer. The first metallic layer and the second metallic layer are encapsulated with a dielectric material to form the routable substrate comprising the routable conductive traces on a first side thereof. The conductive interconnects have first and second ends which are in electrical communication with the routable conductive traces and with a second side of the routable substrate which is opposite to the first side respectively. Thereafter, a plurality of LED dice is mounted on the routable conductive traces on the first side of the routable substrate for LED illumination of the display panel.

### FIELD OF THE INVENTION

The invention relates to display panels, and in particular to display panels fabricated using routable substrates.

### BACKGROUND AND PRIOR ART

The technology challenges faced in large-format display panels, in particular LED display panels, include improving the light emission resolution, viewable angle and reliability. Such objectives are to some extent limited by conventional fabrication methods of manufacturing display panels, which require light pixels comprising red, green and blue dice to be bonded into individual housings or containers.

FIG. 1 illustrates a conventional single RGB package cup 100 for mounting LED chips onto a display panel. Each pixel point on the display panel comprises red, green and blue LED dice (not shown) mounted into the single RGB package cup 100, which comprises electric contacts 102 for mounting the respective LED dice. The RGB package cup 100 also comprises a substantially vertical side wall 104 surrounding the LED dice that are mounted. As a result, the need for the RGB package cup 100 limits an ability to reduce an area that is physically occupied by an individual pixel, and a pitch between adjacent pixels. Moreover, the side wall 104 partially blocks the emission of light from the RGB package cup 100 for a variety of emission angles, such that a range of the light emitting angles of light rays from the RGB package cup is restricted and limits illumination.

It would be desirable to be able to overcome the aforesaid shortcomings of the prior art.

### SUMMARY OF THE INVENTION

It is thus an object of the invention to seek to provide a display panel that avoids the need for RGB package cups that are used in conventional display panels.

According to a first aspect of the invention, there is provided a method for manufacturing a display panel including a routable substrate, the method comprising the steps of: depositing a first metallic layer for forming routable conductive traces; depositing a second metallic layer for forming conductive interconnects, the second metallic layer having a pattern which is different from the first metallic layer; encapsulating the first metallic layer and the second metallic layer with a dielectric material to form the routable substrate comprising the routable conductive traces on a first side thereof, the conductive interconnects further having first and second ends which are in electrical communication with the routable conductive traces and with a second side of the routable substrate which is opposite to the first side respectively; and thereafter mounting a plurality of LED dice on the routable conductive traces on the first side of the routable substrate for LED illumination of the display panel.

According to a second aspect of the invention, there is provided a routable substrate for manufacturing a display panel, the routable substrate comprising: a substrate in the form of a dielectric encapsulant having opposite first and second sides; electrical connections in the form of routable conductive traces formed from a first metallic layer on the first side of the carrier, the routable conductive traces being configured for electrically mounting a plurality of LED dice on the first side for LED illumination of the display panel; and conductive interconnects encapsulated in the dielectric carrier formed from a second metallic layer having a pattern that is different from the first metallic layer, the conductive interconnects further having first and second ends which are in electrical communication with the routable conductive traces and the second side of the carrier respectively.

According to a third aspect of the invention, there is provided a display panel comprising: a substrate in the form of a dielectric encapsulant having opposite first and second sides; electrical connections in the form of routable conductive traces formed from a first metallic layer on the first side of the carrier; a plurality of LED dice mounted on the routable conductive traces for LED illumination of the display panel; and conductive interconnects encapsulated in the dielectric carrier formed from a second metallic layer having a pattern that is different from the first metallic layer, the conductive interconnects further having first and second ends which are in electrical communication with the routable conductive traces and the second side of the carrier respectively.

According to a fourth aspect of the invention, there is provided a display panel comprising an assembly of a plurality of display sub-panels, each display sub-panel further comprising: a substrate in the form of a dielectric encapsulant having opposite first and second sides; electrical connections in the form of routable conductive traces formed from a first metallic layer on the first side of the carrier; a plurality of LED dice mounted on the routable conductive traces for LED illumination of the display panel; and conductive interconnects encapsulated in the dielectric carrier formed from a second metallic layer having a pattern that is different from the first metallic layer, the conductive interconnects further having first and second ends which are in electrical communication with the routable conductive traces and the second side of the carrier respectively.

It would be convenient hereinafter to describe the invention in greater detail by reference to the accompanying drawings which illustrate a specific preferred embodiment of the invention. The particularity of the drawings and the related description is not to be understood as superseding the generality of the broad identification of the invention as defined by the claims.

### BRIEF DESCRIPTION OF THE DRAWINGS

An example of a display panel formed from a routable substrate in accordance with the invention will now be described with reference to the accompanying drawings, in which:

FIG. 1 illustrates a conventional single RGB package cup for mounting LED chips onto a display panel;

FIG. 2 is a schematic illustration of a substrate on which LED dice are mounted for forming an LED display panel;

FIG. 3 is a schematic illustration of a substrate on which LED dice are mounted for forming an LED display panel, which comprises an additional layer of copper traces on a bottom surface of the substrate;

FIG. 4 is an exemplary control circuit for a display panel comprising an array of mounted LED dice;

FIGS. 5A and 5B are respectively side and top views illustrating a first metallic layer formed on a substrate carrier;

FIGS. 6A and 6B are respectively side and top views of a connection build and a dielectric layer added to the substrate carrier of FIGS. 5A and 5B,

FIGS. 7A and 7B are respectively side and top views of a second metallic layer added to the connection build illustrated in FIGS. 6A and 6B;

FIGS. 8A and 8B are respectively side and bottom views of the substrate wherein the substrate carrier supporting the substrate has been removed and LED dice have been mounted onto the substrate; and

FIG. 9 is an illustration of a plurality of sub-panels that has been clustered together to form a larger display panel comprising multiple sub-panels.

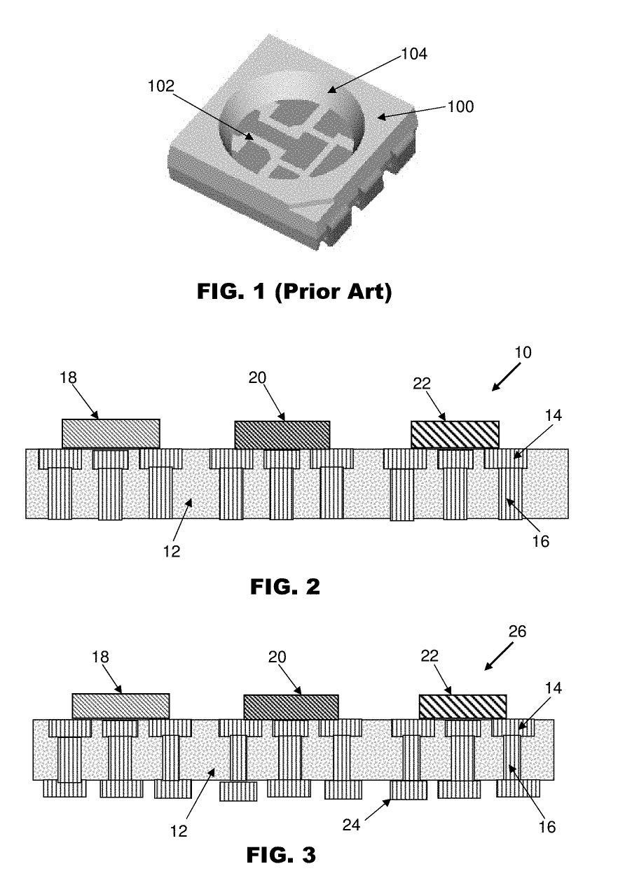

### DETAILED DESCRIPTION OF THE PREFERRED EMBODIMENT OF THE INVENTION

FIG. 2 is a schematic illustration of a routable substrate 10 on which LED dice 18, 20, 22 are mounted for forming an LED display panel. The substrate 10 is able to facilitate fine pitch flip chip mounting of LED dice or standard wire-bonding of the LED dice to form electrical connections between the LED dice and the substrate 10. The substrate 10 is generally made up of a dielectric encapsulant 12 that acts as a carrier. The encapsulant 12 may be in the form of an insulating molding compound having high thermal conductivity, and may comprise epoxy resin and silica-based fillers. The encapsulant 12 should preferably have a low modulus of elasticity that allows flexibility and bendability. The encapsulant 12 should preferably be black in color to provide better LED pixel contrast for use in the LED display panel. The encapsulant 12 should also be susceptible to grinding so as to reduce the thickness of the substrate down to 70 microns in thickness for addressing thinner LED package requirements.

Electrical connections 14 on the substrate 10 are in the form of embedded routable copper traces that are capable of a pitch of at least 30 microns as well as being configurable as a thermal pad design. The substrate 10 also includes conductive connectors, which may be in the form of fully copper-plated via or vertical connectors 16, that function as electrical interconnect or surface-mount pads. The vertical connectors 16 are in contact with the electrical connections 14, and have first and second ends that are in electrical communication with top and bottom sides of the encapsulant 12 respectively. The vertical connectors 16 may also serve as a channel that enables efficient heat dissipation from the thermal pads comprising the electrical connections 14 through heat conduction along the vertical connectors 16.

The substrate 10 is useable for a single LED unit or a multiple LED units configuration.

FIG. 3 is a schematic illustration of a substrate on which LED dice 18, 20, 22 are mounted for forming an LED display panel, which comprises an additional layer of copper traces 24 on a bottom surface of the substrate 26. In the configuration of this substrate 26, a secondary signal layer comprising copper traces 24 is added on an opposite side of the substrate 26 from where the LED dice 18, 20, 22 are mounted, to cater for high-density routing design requirements. The copper traces 24 also function as thermal pads in cooperation with the vertical connectors 16 for enhanced heat dissipation from the bottom surface of the substrate 26.

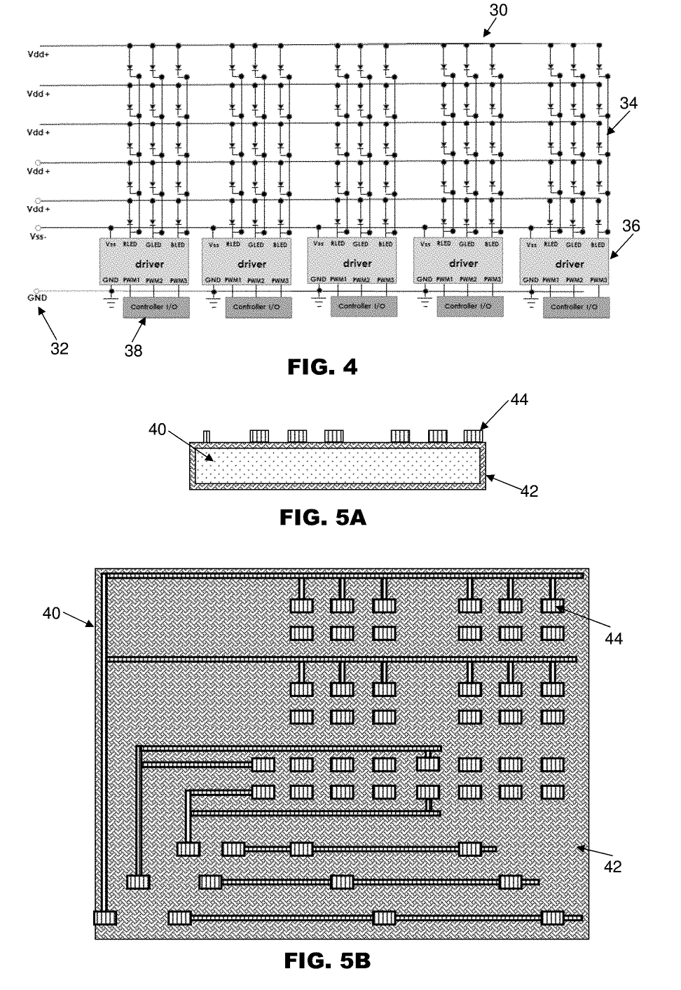

FIG. 4 is an exemplary control circuit 30 for a display panel comprising an array of mounted LED dice. The control circuit comprises a voltage source 32, which includes positive and negative voltage points, and a ground point. A plurality of contact points 34 is included for making electrical connections with the LED dice 18, 20, 22 that are mounted. There are drivers 36 incorporated for driving illumination of the LED dice, and controller I/Os 38 used for correspondingly controlling the drivers 36. Each individual pixel comprising multiple LED dice 18, 20, 22 may thus be controllable by a single controller I/O 38 and a single driver 36.

FIG. 5A is a side view of a first metallic layer 44 formed on a substrate carrier 40. The substrate carrier 40 comprises stainless steel, and may be further plated with an external copper layer 42 which functions as a seed layer allowing the first metallic layer 44 to be plated over the substrate carrier 40. The first metallic layer 44 is formed by first depositing a patterned photo-resist layer (not shown) on the substrate carrier 40 using a photosensitive dry film. A pattern on the photo-resist layer will correspond to a desired pattern of the first metallic layer 44, which would form routable conductive traces on the routable substrate 10. The substrate carrier 40 goes through a metal deposition process during which the first metallic layer 44 is electroplated onto the substrate carrier 40 with the photo-resist layer acting as a mask. The first metallic layer 44 may comprise multiple metal layers, such as respective gold, nickel and copper layers. Alternatively, the first metallic layer 44 may comprise a single metal layer, such as a copper layer only.

FIG. 5B is a top view of the substrate carrier 40 illustrated in FIG. 5A, with patterns of the first metallic layer 44 formed on the substrate carrier 40, which may further comprise an external plated copper layer 42.

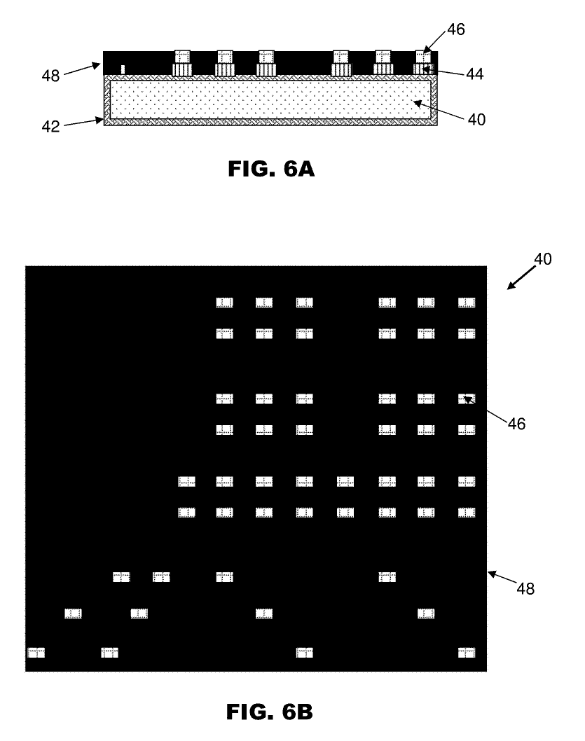

FIGS. 6A and 6B are respectively side and top views of a second metallic layer 46 and a dielectric layer 48 added to the substrate carrier 40 of FIGS. 5A and 5B. The second metallic layer 46 is in the form of a connection build for forming conductive via interconnects, and which may further function as a heatsink. The second metallic layer 46 is formed by depositing a patterned photo-resist layer (not shown) over the first metallic layer 44 using a photosensitive dry film. A pattern on the photo-resist layer will correspond to a desired pattern of the second metallic layer 46 to be plated on top of the first metallic layer 44. The second metallic layer 46 would have a different pattern from the first metallic layer 44 for routing purposes.

The substrate carrier 40 goes through a metal deposition process during which the second metallic layer 46 is electroplated onto the first metallic layer 44 with the photo-resist layer acting as a mask. The second metallic layer 46 may comprise copper.

The first metallic layer 44 and the second metallic layer 46 are then encapsulated by a dielectric layer 48. The dielectric layer 48 may comprise a molding compound which includes epoxy resin and silica fillers. Such encapsulation may be performed by transfer or injection molding, compression molding or by a film molding lamination process.

As the dielectric layer 48 would often cover the top of the second metallic layer 46 after encapsulation, the top portion of the dielectric layer 48 should be removed, such as by grinding, buffing or chemical planarization, in order to expose the top surfaces of the second metallic layer 46. It would be observed that the first metallic layer 44 is located on a first side of the routable substrate 10. The second metallic layer 46 has first and second ends which hare in electrical communication with the first metallic layer 44 on the first side, and in electrical communication with a second side which is opposite to the first side respectively.

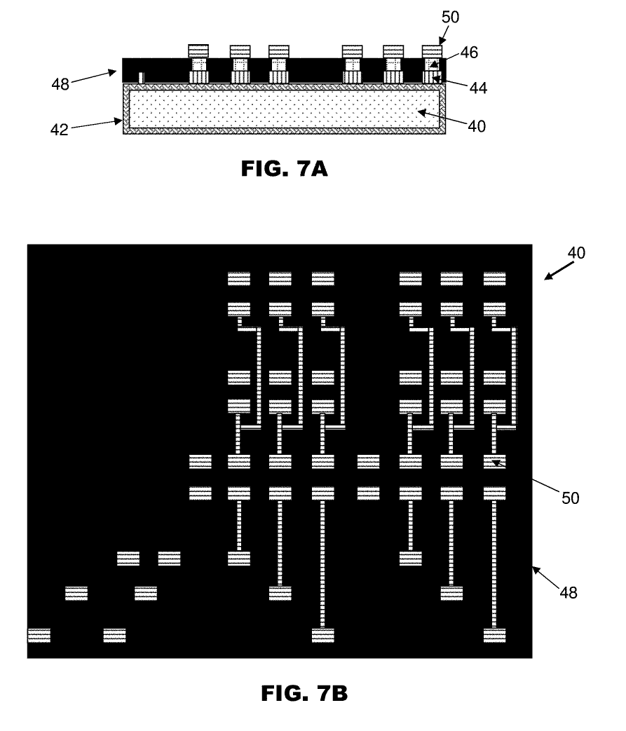

In order to form the substrate structure illustrated in FIG. 7A, a sacrificial conductive seed layer is first formed such as by electroless plating or sputtering, preferably of copper material onto the dielectric layer 48. This is followed by creating a patterned photo-resist layer (not shown) over the conductive seed layer using a photosensitive dry film. A third metallic layer 50 is then formed using a metal deposition process during which the third metallic layer 50 is electroplated onto the conductive seed layer with the photo-resist layer acting as a mask. The third metallic layer 50 preferably comprises copper material. Thereafter, a chemical stripping process is conducted to remove the entire photo-resist layer, and light chemical etching is conducted to remove the thin conductive seed layer. Hence, the pattern of the third metallic layer 50 is isolated to form an electrical circuit on top of the second metallic layer 46.

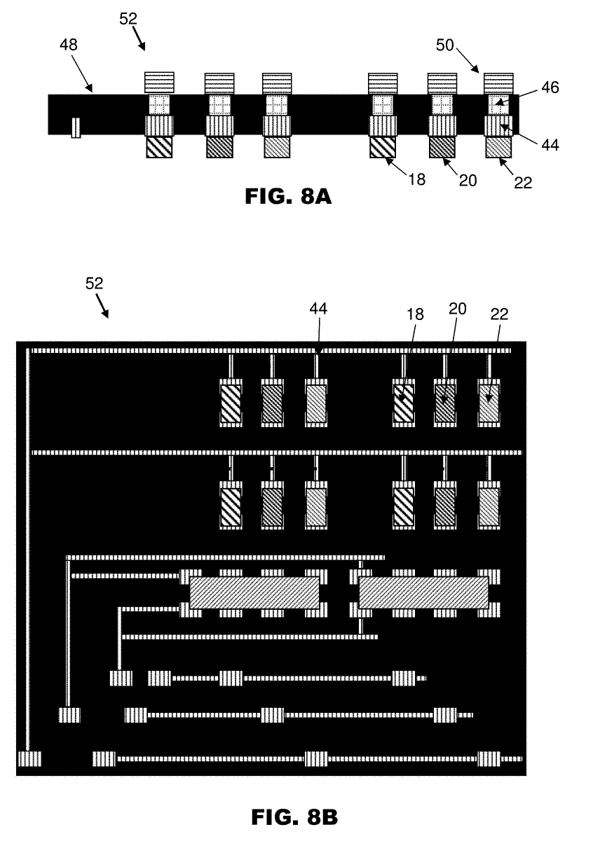

FIGS. 8A and 8B are respectively side and bottom views of the substrate wherein the substrate carrier 40 supporting the substrate has been removed and LED dice 18, 20, 22 have been mounted onto the routable conductive traces formed by the first metallic layer 44 of the routable substrate 10. In particular, the substrate carrier 40 has been removed by suitable removal means, such as mechanical peeling, chemical etching or other suitable processes prior to mounting the LED dice 18, 20, 22. An electrical circuit as shown in FIG. 8B, comprising mainly the first metallic layer 44, is revealed by the removal of the substrate carrier 40.

The first metallic layer 44, which may comprise respective gold, nickel and copper layers or a single layer of copper, is adapted for the mounting of LED dice. The red, blue and green LED dice 18, 20, 22 are bonded to the first metallic layer 44 on the first side of the routable substrate 10, and electrical connections between the LED dice and the first metallic layer 44 are established. Each set of three LED dice 18, 20, 22 will cooperate to form a display pixel when they are driven to illuminate. The opposite second side of the routable substrate 10 is mountable on the control circuit 30 comprising the voltage source 32 and drivers 36 as illustrated in FIG. 4, wherein the third metallic layer 50 comprising copper is adapted to be electrically connected to the control circuit 30 to drive and control the illumination of the LED dice 18, 20, 22.

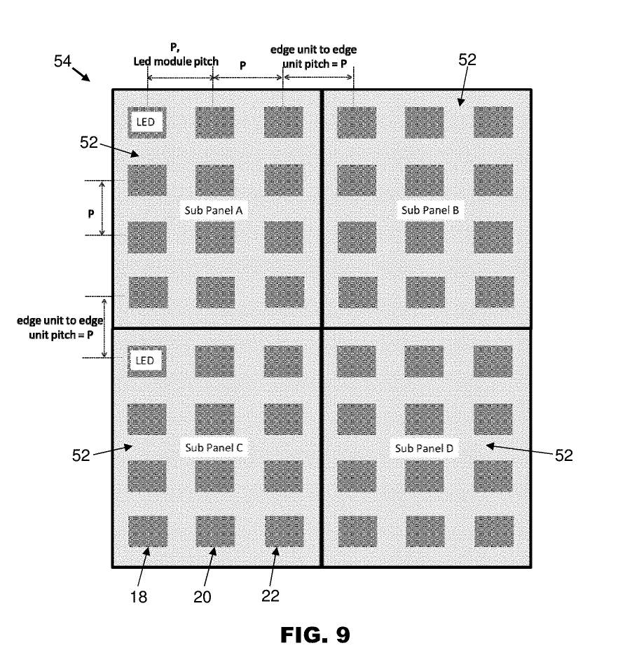

FIG. 9 is an illustration of a plurality of sub-panels 52 that has been clustered together to form a larger display panel 54 comprising multiple sub-panels 52. Each sub-panel 52 comprises a plurality of sets of LED dice 18, 20, 22 which is mounted as described with reference to FIGS. 8A and 8B above, and they are separated by pitch P. FIG. 9 shows the ability to assemble the larger display panel 54 modularly, such that the making of the substrates can be facilitated by producing them in a smaller form factor. Thereafter, each smaller form factor substrate which forms a sub-panel 52 can be combined with other similar or identical sub-panels 52 to form a larger display panel 54. Accordingly, various sizes of display panels 54 may be manufactured modularly using this approach.

In respect of the display panel 54 formed from a combination of sub-panels 52, it should be appreciated that the control circuit 30 as illustrated in FIG. 4 would be modified such that all the drivers 36 and the controller I/Os 38 are located on a side of the sub-panels 52 that is opposite to the side where the LED dice 18, 20, 22 are mounted. This is in order to maintain a same pitch P across all the LED modules in the separate sub-panels 52.

The invention described herein is susceptible to variations, modifications and/or additions other than those specifically described and it is to be understood that the invention includes all such variations, modifications and/or additions which fall within the spirit and scope of the above description.

1. A method for manufacturing a display panel including a routable substrate, the method comprising the steps of:
depositing a first metallic layer for forming routable conductive traces;
depositing a second metallic layer for forming conductive interconnects, the second metallic layer having a pattern which is different from the first metallic layer;
encapsulating the first metallic layer and the second metallic layer with a dielectric material to form the routable substrate comprising the routable conductive traces on a first side thereof, the conductive interconnects further having first and second ends which are in electrical communication with the routable conductive traces and with a second side of the routable substrate which is opposite to the first side respectively; and thereafter
mounting a plurality of LED dice on the routable conductive traces on the first side of the routable substrate for LED illumination of the display panel.

2. The method as claimed in claim 1, wherein the conductive interconnects comprise via or vertical connectors.

3. The method as claimed in claim 1, further comprising the step of forming a third metallic layer as a secondary signal layer prior to finishing the routable substrate.

4. The method as claimed in claim 3, further comprising the step of forming a sacrificial conductive seed layer over the second metallic layer prior to depositing the third metallic layer onto the conductive seed layer.

5. The method as claimed in claim 3, wherein the third metallic layer comprises copper.

6. The method as claimed in claim 1, wherein the first metallic layer is deposited on a substrate carrier comprising stainless steel.

7. The method as claimed in claim 6, wherein the stainless steel substrate carrier is plated with an external copper layer which functions as a seed layer for plating the first metallic layer.

8. The method as claimed in claim 6, further comprising the step of removing the substrate carrier prior to mounting the plurality of LED dice on the routable conductive traces.

9. The method as claimed in claim 1, wherein the dielectric material comprises an insulating molding compound having high thermal conductivity.

10. The method as claimed in claim 9, wherein the molding compound has a low modulus of elasticity that allows for flexibility and bendability.

11. The method as claimed in claim 1, further comprising the step of mounting the second side of the routable substrate on a control circuit comprising a voltage source and drivers for driving illumination of the plurality of LED dice.

12. The method as claimed in claim 1, wherein the first metallic layer comprises respective gold and nickel layers.

13. The method as claimed in claim 12, wherein the second metallic layer comprises copper.

14. A routable substrate for manufacturing a display panel, the routable substrate comprising:
a substrate in the form of a dielectric encapsulant having opposite first and second sides;
electrical connections in the form of routable conductive traces formed from a first metallic layer on the first side of the carrier, the routable conductive traces being configured for electrically mounting a plurality of LED dice on the first side for LED illumination of the display panel; and
conductive interconnects encapsulated in the dielectric carrier formed from a second metallic layer having a pattern that is different from the first metallic layer, the conductive interconnects further having first and second ends which are in electrical communication with the routable conductive traces and the second side of the carrier respectively.

15. A display panel comprising:
a substrate in the form of a dielectric encapsulant having opposite first and second sides;
electrical connections in the form of routable conductive traces formed from a first metallic layer on the first side of the carrier;
a plurality of LED dice mounted on the routable conductive traces for LED illumination of the display panel; and
conductive interconnects encapsulated in the dielectric carrier formed from a second metallic layer having a pattern that is different from the first metallic layer, the conductive interconnects further having first and second ends which are in electrical communication with the routable conductive traces and the second side of the carrier respectively.

16. The display panel as claimed in claim 15, wherein the display panel comprises a display sub-panel, which is configured to be mountable with one or more other similar display sub-panels for modularly assembling a display panel which is larger than the display sub-panel.

17. A display panel comprising an assembly of a plurality of display sub-panels, each display sub-panel further comprising:
a substrate in the form of a dielectric encapsulant having opposite first and second sides;
electrical connections in the form of routable conductive traces formed from a first metallic layer on the first side of the carrier;
a plurality of LED dice mounted on the routable conductive traces for LED illumination of the display panel; and
conductive interconnects encapsulated in the dielectric carrier formed from a second metallic layer having a pattern that is different from the first metallic layer, the conductive interconnects further having first and second ends which are in electrical communication with the routable conductive traces and the second side of the carrier respectively.
